(19) United States
(12) Patent Application Publication
(10) Pub. No.: US 2014/0147996 A1
(43) Pub. Date: May 29, 2014

(54) METHODS FOR FABRICATING BULK HETEROJUNCTIONS USING SOLUTION PROCESSING TECHNIQUES

(71) Applicants: Bryan D. Vogt, Fairtawn, OH (US); Jian Li, Tempe, AZ (US); Choong-Do Park, Tempe, AZ (US)

(72) Inventors: Bryan D. Vogt, Fairtawn, OH (US); Jian Li, Tempe, AZ (US); Choong-Do Park, Tempe, AZ (US)

(73) Assignee: Arizon Board of Regents Acting for and on Behalf Arizona State University, Scottsdale, AZ (US)

(21) Appl. No.: 13/989,683

(22) PCT Filed: Nov. 28, 2011
(86) PCT No.: PCT/US11/62203

§ 371 Date: Dec. 11, 2013

Related U.S. Application Data
(60) Provisional application No. 61/417,502, filed on Nov. 29, 2010.

(51) Int. Cl. H01L 21/02

(52) U.S. Cl. CPC H01L 21/02628
USPC 438/497

(57) ABSTRACT

Solvent mixtures useful for processing bulk heterojunction materials and methods for selecting the same are disclosed, wherein Hansen solubility parameters are utilized to select the solvent mixture. A solvent system using a fully nonhalogenated solvent mixture is disclosed. Also disclosed is a solvent mixture containing 20 vol. % acetophenone (AP) in mesitylene (MS), wherein the performance of the solvent system is comparable to dichlorobenzene.

### BACKGROUND

1. Technical Field

The present disclosure relates to heterojunction materials, and specifically to methods for fabricating a heterojunction using solution processing techniques.

2. Technical Background

Semiconductor materials and heterojunction composites thereof are of significant interest for use in light absorbing and light emitting devices. Traditional organic solar cell devices can contain multiple layers, for example, an anode, a donor-type material, an acceptor-type material, an exciton blocking material, and a cathode. In recent years, significant research has been employed in the processing of semiconductor materials for such applications, but further developments are needed to facilitate the use of these materials in electronic devices.

Techniques utilized for processing traditional silicon based materials are not compatible with plastic substrates due to, for example, temperature limitations. Similarly, plastic photovoltaic devices suffer from limited exciton diffusion lengths, such that only excitons near the p-n interface can be collected. Other processing techniques utilize high temperature steps, for example, to sinter titania particles.

Bulk heterojunction (BHJ) materials, wherein donor and acceptor materials are mixed together to form a blend or dispersed heterojunction, can provide improved performance due to the shorter exciton diffusion path to a material junction. Existing solution processing techniques can provide bulk heterojunctions from phase separated materials, but utilize halogenated solvents to achieve reasonable efficiencies.

Thus, a need exists for methods that can provide simple, efficient, and low-cost flexible bulk heterojunction materials while minimizing environmental and health impact (i.e., avoid use of halogenated solvents). This need and other needs are satisfied by the various methods of the present invention.

### SUMMARY

The present invention relates to heterojunction materials, and specifically to methods for fabricating a heterojunction using solution processing techniques.

In one aspect, the present disclosure provides a method for preparing a bulk heterojunction material, the method comprising contacting a donor material and an acceptor material with a solvent system comprising at least two individual solvents, wherein the at least two individual solvents have different boiling points.

In a second aspect, the present disclosure provides a method as described above, wherein the solvent system does not comprise a halogenated compound.

In a third aspect, the present disclosure provides a method as described above, wherein the solvent system does not comprise dichlorobenzene.

In a fourth aspect, the present disclosure provides a method as described above, wherein the solvent system dissolves at least a portion of the donor material and at least a portion of the acceptor material.

In another aspect, the present disclosure provides a method as described above, wherein the solvent system dissolves all or substantially all of both the donor material and the acceptor material.

In another aspect, the present disclosure provides a method as described above, wherein at least one of the Hansen solubility parameters of the solvent system is substantially similar to that of dichlorobenzene during drying.

Also disclosed are devices, such as organic light emitting devices and photovoltaic devices (e.g., solar cells) that comprise heterojunction materials made from the various methods of the present invention.

### BRIEF DESCRIPTION OF THE FIGURES

The accompanying figures, which are incorporated in and constitute a part of this specification, illustrate several aspects and together with the description serve to explain the principles of the invention.

FIG. 1 illustrates a conventional layered organic solar cell, wherein the EBL is an exciton blocking material and ITO represents an indium tin oxide anode.

FIG. 2 is a schematic illustration of four consecutive steps in the generation of photocurrent from light incident on a donor-acceptor heterojunction photovoltaic cell: 1) photon absorption with efficiency η_{A}, 2) exciton diffusion, where the fraction of excitons reaching the donor-acceptor junction is η_{ED}, 3) the charge transfer reaction with efficiency η_{CT}, and 4) collection of the carriers at the electrodes, with efficiency η_{CC}.

FIG. 3 illustrates the current-voltage characteristics of a comparative ITO/P3HT:PCBM (1:1) 110 nm/BCP 14 nm/Al device structure prepared from dichlorobenzene, under illumination of AMI 1.5 at 100 mW/cm².

FIG. 4 illustrates an exemplary three dimensional plot of solvents, based on Hansen parameters, in accordance with various aspects of the present invention.

FIG. 5 illustrates the current-voltage characteristics of an inventive ITO/P3HT:PCBM (1:1) 60-70 nm/BCP 14 nm/Al device structure prepared from a mixture of mesitylene and acetophenone, under illumination of AMI 1.5 at 100 mW/cm², in accordance with various aspects of the present invention.

FIG. 6 illustrates UV-Vis absorption spectra obtained for P3HT:PCBM blend thin films cast from dichlorobenzene (DCB), mesitylene (MS) and 80 vol. % MS-20 vol. % acetophenone (AP) mixture after thermal annealing at 140° C. for 30 min, in accordance with various aspects of the present invention.

FIG. 7 illustrates: a) the J-V characteristics under illumination of 100 mWcm⁻² (AM 1.5 G), and b) the external quantum efficiency (EQE) measurements data for devices fabricated from DCB, MS, and a 80 vol. % MS-20 vol. % AP mixture.

FIG. 8 illustrates atomic force microscopy topography and phase images of P3HT/PCBM blend films cast from (a, b) MS, (c,d) 80 vol. % MS-20 vol. % AP mixture, and (e, f) DCB.

FIG. 9 illustrates an exemplary mechanism for film formation, in accordance with various aspects of the present invention.

Additional aspects of the invention will be set forth in part in the description which follows, and in part will be obvious from the description, or can be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### DESCRIPTION

The present invention can be understood more readily by reference to the following detailed description of the invention and the Examples included therein.

Before the present compounds, devices, and/or methods are disclosed and described, it is to be understood that they are not limited to specific synthetic methods unless otherwise specified, or to particular reagents unless otherwise specified, as such can, of course, vary. It is also to be understood that the terminology used herein is for the purpose of describing particular aspects only and is not intended to be limiting. Although any methods and materials similar or equivalent to those described herein can be used in the practice or testing of the present invention, example methods and materials are now described.

As used in the specification and the appended claims, the singular forms “a,” “an” and “the” include plural referents unless the context clearly dictates otherwise. Thus, for example, reference to “a component” includes mixtures of two or more components.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “optional” or “optionally” means that the subsequently described event or circumstance can or can not occur, and that the description includes instances where said event or circumstance occurs and instances where it does not.

Disclosed are the components to be used to prepare the compositions of the invention as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds can not be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the invention. Thus, if there are a variety of additional steps that can be performed it is understood that each of these additional steps can be performed with any specific embodiment or combination of embodiments of the methods of the invention.

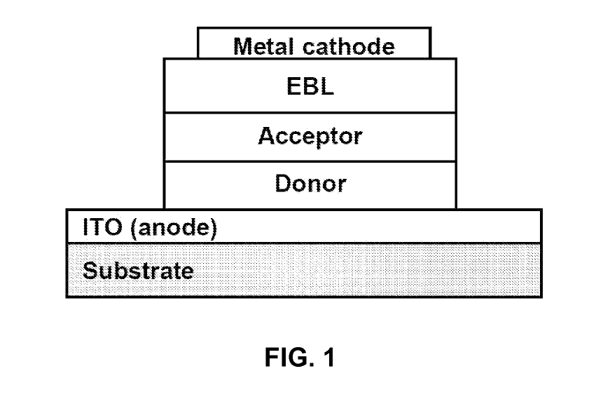

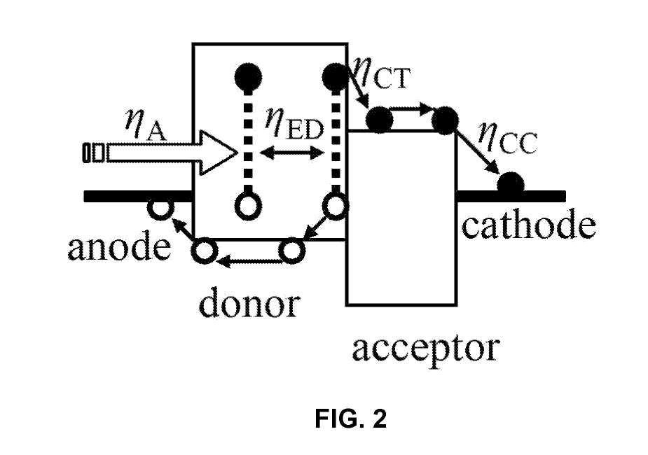

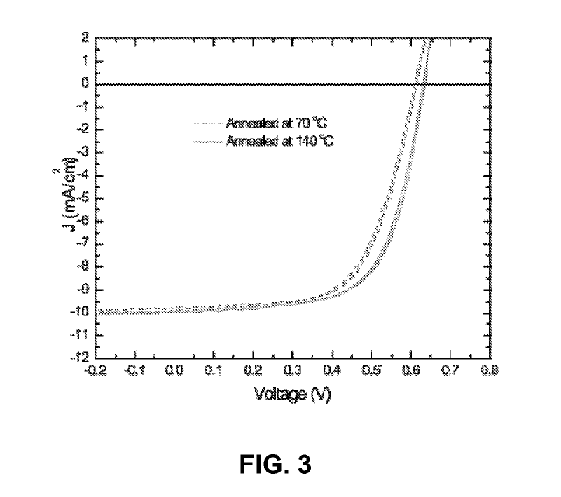

A conventional organic solar cell device, as illustrated in FIG. 1, can include a layer of indium tin oxide as an anode, a single layer of a donor-type material, a single layer of a acceptor-type material, a single layer of an exciton blocking material, and a layer of metal cathode. In such a conventional organic solar cell device, there are four steps in the generation of a photocurrent from light incident on the donor-acceptor heterojunction in a photovoltaic cell. These steps, as illustrated in FIG. 2, include 1) photon absorption with efficiency η_{A}, 2) exciton diffusion, where the fraction of excitons reaching the DA junction is η_{ED}, 3) the charge transfer reaction with efficiency η_{CT}, and 4) collection of the carriers at the electrodes, with efficiency η_{CC}.

In one aspect, an efficient photovoltaic cell should have at least one of a high photon absorption efficiency (η_{A}), a high exciton diffusion efficiency (η_{ED}), a high charge transfer efficiency (η_{ED}), and/or a high carrier collection efficiency (η_{CC}). It is desirable that each of these efficiencies be high.

In another aspect, the morphology of the dispersed heterojunction layer (mixed donor and acceptor layer) can have a significant impact on the performance of a device formed from the bulk heterojunction material. In such an aspect, control of the morphology can ensure efficient charge dissociation and transport.

Dichlorobenzene is the solvent most commonly utilized for traditional poly(3-hexylthiophene): [6,6]-phenyl-C₆₁-butyric acid methyl ester (P3HT:PCBM) cells, but dichlorobenzene is toxic and environmentally hazardous. Moreover, it is not suitable for the fabrication of large area devices.

As briefly described above, the present disclosure relates to bulk heterojunction materials and methods for preparing such bulk heterojunction materials using solution processing techniques. In one aspect, the methods of the present disclosure comprise selecting a solvent or solvent system that can provide a film having desirable performance properties. In another aspect, the present disclosure provides methods for the fabrication of bulk heterojunction materials and devices comprising the same, wherein the methods do not utilize a halogenated solvent. In a specific aspect, the methods do not utilize dichlorobenzene. In another aspect, the methods do not utilize dichlorobenzene or other derivatives or substituted versions thereof.

A variety of compounds and mixtures of compounds can be utilized for BHJ materials. In one aspect, a blend of poly(3-hexylthiophene) (P3HT) and [6,6]-phenyl-C₆₁-butyric acid methyl ester (PCBM) can be used to form a bulk heterojunction. In another aspect, other materials, such as, for example, poly[2-methoxy-5-(2′-ethylhexyloxy)-p-phenylene vinylene] (MEH-PPV), poly-(3-octylthiophene) (P3OT), cyano-polyphenylene vinylene (CN—PPV), Poly(3,4-ethylenedioxythiophene) (PEDOT), poly(styrenesulfonate) (PSS), fullerene based materials, such as bis(dimethylphenylsilylmethyl)(60)fullerene, and/or combinations thereof can be utilized. In still other aspects, other materials, precursors, and/or combinations known to those of skill in the art or that are developed hereafter can be utilized. One of skill in the art would readily be able to select appropriate materials for use in the methods of the present disclosure. Accordingly, the present disclose is not intended to be limited to any particular compound or semiconductor material for use in forming a bulk heterojunction material.

Conventional solution based processing techniques for bulk heterojunction materials utilize halogenated solvents, such as, for example dichlorobenzene. Such halogenated solvents present significant environmental, health, and handling concerns, and are not feasible for use in large scale manufacturing processes. In one aspect, the present invention provides methods for the preparation of bulk heterojunction materials that do not utilize halogenated solvents. In another aspect, the methods of the present invention can provide films and devices having performance approximating, equivalent to, or superior to bulk heterojunction materials prepared from conventional halogenated solvents, such as, for example, dichlorobenzene.

In one aspect, the methods of the present invention comprise a solvent system to dissolve donor and acceptor materials. The solvent system and/or the solvent system containing the donor and acceptor materials can optionally be heated to facilitate dissolution of all or a portion of the donor and acceptor materials in the solution. The resulting solution can then be utilized to fabricate a film of the blended donor and acceptor materials.

The solution of donor and acceptor materials can be coated and/or deposited onto a substrate and/or an electrode surface via any suitable technique. In one aspect, the solution can be spin coated onto a substrate. In another aspect, the solution can be contacted or applied to at least a portion of a substrate or electrode surface via spin coating, drop casting, dip coating, spraying, doctor blade, or other technique. One of skill in the art could readily select an appropriate technique for application of a solution onto a substrate or electrode surface.

After application of the solution to at least a portion of a substrate or electrode surface, the applied solution can be dried or allowed to dry. In one aspect, the solution can be allowed to evaporate and/or dry under ambient conditions. In another aspect, evaporation of the solution can be facilitated by various techniques, such as, for example, heating, vacuum, or movement of air. Adjustment and/or control of the solvent evaporation (i.e., drying) can optionally be accomplished via solvent annealing, thermal annealing, and/or the use of solvent additives or mixtures. In one aspect, as described herein, the evaporation rate of each of the solvents in a solvent system can be tailored so as to form a gradient in solvent properties during the drying and/or evaporation process. In another aspect, such a gradient can influence the distribution of components within the film.

In one aspect, the solvent system comprises a blend of 2 or more solvents. In a specific aspect, the solvent system is two solvents. In another aspect, the solvent system can comprise more than two solvents. In yet another aspect, the solvent system can comprise other components, such as, for example, dispersants, stabilizers, or other additives or combinations thereof. In another aspect, at least two of the individual solvents within a solvent system have different boiling points.

In another aspect, the solvent system can comprise at least one polar solvent and one non-polar solvent. It should be understood that the terms polar and non-polar are relative terms and that no specific thresholds are intended that could limit the use of a particular solvent. Moreover, while exemplary solvents are recited in this disclosure, the present invention is not intended to be limited to any particular recited solvent. One of skill in the art, in possession of this disclosure, could readily select an appropriate solvent or solvent system for preparing a bulk heterojunction material.

In one aspect, a mixture of a polar solvent, such as mesitylene, and a non-polar solvent, such as acetophenone, can be utilized as a solvent system. In such an aspect, poly(3-hexyl thiophene) (P3HT) and phenyl-C61-butyric acid methyl ester (PCBM) in a 80-20 nonpolar/polar mixture of these solvents can yield a high performance organic device (3.5% efficiency) upon spin coating onto a PEDOT:PSS modified ITO electrode on glass. In one aspect, the performance of such a device is comparable to that of a conventional P3HT:PCBM film of similar thickness cast from dichlorobenzene.

In addition to elimination of halogenated solvents, the methods of the present invention can provide the ability to tune or adjust the morphology of a resulting BHJ film.

In one aspect, one or more solvents of a desired solvent system can be selected based on Hansen solubility parameters. Solubility parameters can be utilized to better understand the solubility of polymers, such as donor or acceptor materials, in solvent mixtures. By approximately matching the solubility parameters of a polymer, two non-solvents can be designed to dissolve the polymer or a mixture of polymers. For example, dichlorobenzene has been used to provide high performance photovoltaic devices. Thus, it can be desirable to utilize a solvent system that can provide solvent characteristic similar to dichlorobenzene, but without the disadvantages thereof. In one aspect, Hansen solubility parameters can be utilized to predict the ability of a solvent or solvent system to dissolve a particular solute.

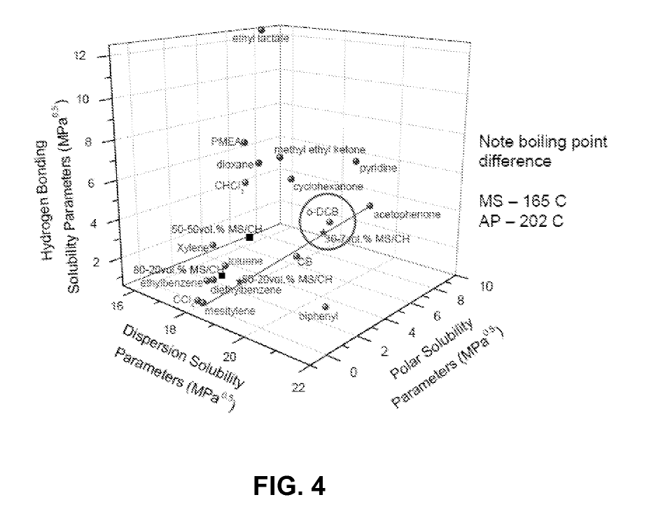

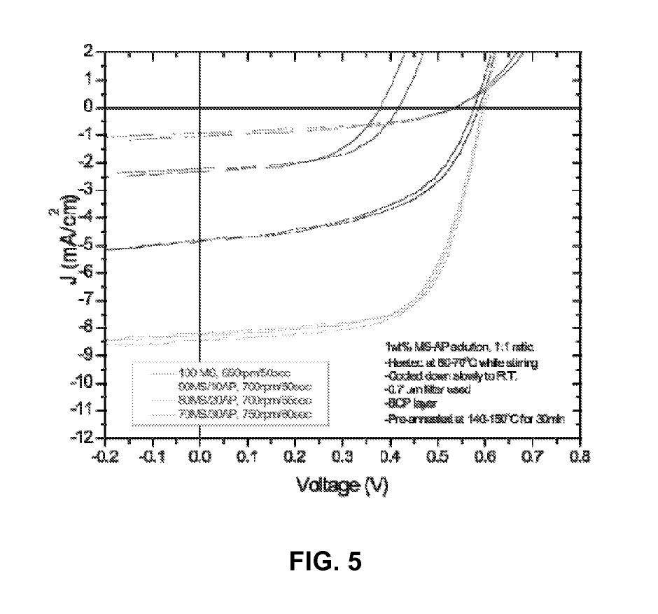

Hansen solubility parameters can be used to describe the cohesive energy of a liquid, using three components: δ_{d} to describe the energy from dispersion bonds between molecules, δₚ to describe energy from dipolar intermolecular forces between molecules, and δₕ to describe energy from hydrogen bonds between molecules. These three parameters (δ_{d}, δₚ, and δₕ) can be illustrated as coordinates in a three-dimensional coordinate system (see FIG. 4). Thus, the closer in proximity two molecules are, the more likely they are to dissolve in each other.

With respect to Hansen solubility parameters, R₀ can be used to describe an interaction radius, for example, to determine whether a solvent is within a desired range. In addition, Rₐ can be used to describe the distance between parameters (for example, (Rₐ)²=4(δ_{d2}−δ_{d1})²+(δₚ₂−δₚ₁)²+(δₕ₂−δₕ₁)²). When combined, Rₐ/R₀ can be used to describe the relative energy difference (RED) between two species, wherein the smaller the relative energy difference, the more likely that substances will dissolve in each other.

It should be noted that Hansen solubility parameters and the applicability to a particular solute or solvent system, can vary with temperature. The specific size and shape of a particular solute or solvent species can also affect the solubility properties thereof, and may or may not be accounted for in the Hansen parameters.

As detailed in Table 1, below, dichlorobenzene has the following Hansen parameters: δ_{d}=19.2, δₚ=6.3, and δₕ=3.3 MPa^{1/2}. It should also be noted that solvents having similar boiling points do not necessarily have similar solubility parameters and can, in some aspects, have significantly differing characteristics.

In one aspect, the present invention comprises a solvent system with at least one Hansen parameter similar to that of dichlorobenzene. In another aspect, the present invention comprises a solvent system with at least two Hansen parameters similar to those of dichlorobenzene. In still another aspect, the present invention comprises a solvent system with three Hansen parameters similar to those of dichlorobenzene. In one aspect, the system selected of polar/non-polar nonhalogenated solvents can come within 0.1 MPa^{1/2} for δ_{d} and δₚ, within 0.4 MPa^{1/2} for δₕ of dichlorobenzene. In other aspects, the variance between a selected solvent system and, for example, dichlorobenzene, for each Hansen parameter can vary and can be less than or greater than any value specifically recited herein. The Hansen parameters are fixed for a single (pure) solvent, so it may be desired to deviate from the target Hansen parameters to obtain the maximum performance. One of skill in the art, in possession of this disclosure, could readily determine an acceptable variation in Hansen parameters.

In one aspect, the present invention comprises a solvent system capable of at least partially dissolving a donor and an acceptor material. In another aspect, the present invention comprises a solvent system capable of at least partially dissolving a P3HT:PCBM blend. In yet another aspect, the present invention comprises a solvent system capable of fully dissolving a donor and an acceptor material.

In one aspect, the inventive solvent system comprises a mixture of mesitylene (MS) and acetophenone (AP). This inventive solvent mixture exhibits solubility parameters that closely mimic dichlorobenzene at a composition of 73 vol % AP (δb_{d}=19.2, δₚ=6.3, δₕ=2.9 MPa^{1/2}). Since the volatility of MS and AP are not matched, the thermodynamic properties and interactions of such a solvent system can change during formation of a film (i.e., during evaporation or drying).

Differences in evaporation rate between the solvents during film formation yield a gradient in solvent quality that can influence the distribution of components within the film. In one aspect, the Hansen parameters and thus, the thermodynamic properties of a solvent system, can be tailored so as to control the interaction between a donor and acceptor material during film formation. For example, a solvent system can be tailored to control the interaction between a P3HT and PCBM material during film formation and drying. In one aspect, devices utilizing such tailored systems can provide efficiencies approaching, equivalent to, or superior to those obtainable from conventional dichlorobenzene prepared films.

In one aspect, the inventive solvent system of the present invention can vary, depending on the particular donor and acceptor materials to be dissolved. One of skill in the art, in possession of this disclosure, could readily select an appropriate solvent system to dissolve a particular donor and acceptor material.

In one aspect, the inventive solvent system comprises one or more good solvents, such as, for example, toluene, xylene, mesitylene, or a combination thereof. In another aspect, other solvents can be used alone or in combination with any of the solvents specifically recited herein. In another aspect, the inventive solvent system further comprises a non-solvent and/or less volatile solvent, such as, for example, cyclohexanone, acetophenone, or a combination thereof. It should be noted that the term non-solvent, as used herein, is not intended to imply that no solubility properties exist, but rather a relative solvent strength as compared to one or more other components of a solvent system.

In various aspects, the inventive solvent system can comprise from about 50 vol. % to about 95 vol % of a first solvent, for example, about 50, 55, 60, 65, 70, 75, 80, 85, 90, or 95 vol. %. In another aspect, the inventive solvent system can comprise from about 50 vol % to about 95 vol % of mesitylene, toluene, xylene, or a combination thereof. In a specific aspect, the inventive solvent system can comprise about 80 vol % mesitylene.

In other aspects, the inventive solvent system can comprise from about 5 vol % to about 50 vol % of a second solvent, for example, about 5, 10, 15, 20, 25, 30, 35, 40, 45, or 50 vol %. In another aspect, the inventive solvent system can comprise from about 5 vol % to about 50 vol % of cyclohexanone, acetophenone, or a combination thereof. In a specific aspect, the inventive solvent system can comprise about 20 vol % of cyclohexanone, acetophenone, or a combination thereof.

In one aspect, the first organic solvent can be one or more solvents disclosed in Table 1, including combinations thereof.

TABLE 1
Examples of the solvent parameters

| | | | | | Molar | Boiling |
|---|---|---|---|---|---|---|
| | | | | | Volume | Point |
| Solvent | δ_{d} | δₚ | δₕ | δₜ | (cm³/mol) | (° C.) |
| o-dichlorobenzene | 19.2 | 6.3 | 3.3 | 20.5 | 112.8 | 180 |
| Toluene | 18 | 1.4 | 2 | 18.2 | 106.8 | 110.6 |
| Xylene | 17.8 | 1 | 3.1 | 18 | 121.2 | 144 |
| Mesitylene (MS) | 18 | 0 | 0.6 | 18 | 139.8 | 164.7 |
| Cyclohexanone (CH) | 17.8 | 6.3 | 5.1 | 19.6 | 104 | 155.6 |
| Acetophenone (AP) | 19.6 | 8.6 | 3.7 | 21.7 | 117 | 202 |
| 80/20 MS/CH mixture | 17.96 | 1.26 | 1.5 | 18.32 | 132.64 | |
| 50/50 MS/CH mixture | 17.9 | 3.15 | 2.85 | 18.8 | 121.9 | |
| 80/20 MS/AP mixture | 18.32 | 1.72 | 1.22 | 18.74 | 149 | |
| 30-70 MS/AP mixture | 19.12 | 6.02 | 2.77 | 20.59 | 129.3 | |

In one aspect, each of the solvents of a particular solvent system are compatible with all or at least a portion of the donor and acceptor materials, and with the substrate and electrode materials to which the donor and acceptor materials are intended to contact.

In one aspect, an inventive solvent system can provide a dispersed heterojunction film having a desired morphology. In another aspect, an inventive solvent system can provide small domains in a coated film, such that interfaces are maximized and the exciton diffusion distance is minimized.

In one aspect, the solvent properties and volatility differences can trigger a phase separation between the donor and acceptor materials during drying. In contrast to techniques known in the art which generate large areas of phase separation, the inventive methods and solvent systems recited herein can, in various aspects, provide small domains. In another aspect, as illustrated in the Examples, atomic force microscopy can be used to compare the domain size of films formed from inventive solvent systems with those formed from other solvents or dichlorobenzene.

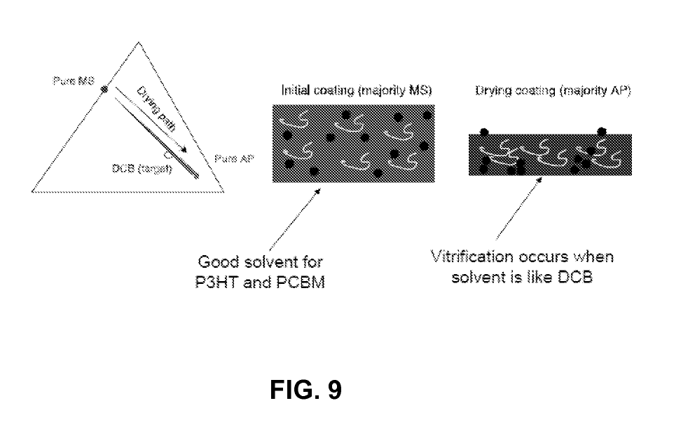

In one aspect, selection of a solvent directly mimicking the Hansen parameters of dichlorobenzene does not provide optimized film formation and performance. In such an aspect, the Hansen parameters do not adequately describe the electrical properties of a solvent. In one aspect, a solvent system comprises at least two solvents and provides solubility parameters matching or similar to dichlorobenzene during the film drying process, such as, for example, at the point when the deposited donor-acceptor material vitrifies. FIG. 9 illustrates an exemplary schematic of a solvent system, in accordance with various aspects of the present disclosure.

Thus, by tuning the relative volatilities of the solvents used, a trajectory of solvent quality during drying is obtained. In one aspect, using a mixture of 80-20 mesitylene:acetophenone can result in the device efficiency being increased by more than a factor of 2. While not wishing to be bound by theory, the concentration of acetophenone is believed to increase during film formation due to the evaporation of mesitylene. As illustrated in Table 1, above, a 30-70 mixture of mesitylene-acetophenone exhibits Hansen Solubility Parameters that mimic that of dichlorobenzene. During drying of a P3HT/PCBM mixture that initially is dissolved in 80-20 mesitylene-acetophenone, the solvent quality takes a trajectory towards the dichlorobenzene.

Thus, the improved device performance of a MS/AP mixed solvent system can originate from two contributions: a decrease in the series resistance (due to improved crystallinity of P3HT upon the addition of AP), and the change in morphology of the active layer caused by the slower evaporation rate of the high boiling point component (AP) in the spin coating and drying process.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary of the invention and are not intended to limit the scope of what the inventors regard as their invention. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

### Example 1

### Preparation of Inventive P3HT/PCBM Blend

In a first example, a P3HT/PCBM blend was prepared. Regioregular P3HT (Rieke Metals, 4002E) and PCBM (Solenne) were dissolved in a 1:1 ratio to 1.0 wt % in either MS (98%, Alfa-Aesar) or a 80 vol. % MS-20 vol. % AP (Sigma-Aldrich) solvent mixture by heating and stirring for 2 h at 75° C. The mixture was then cooled slowly to ambient temperature.

### Example 2

### Preparation of Comparative P3HT/PCBM Blend

In a second example, a comparative P3HT:PCBM blend (1.5 wt %, 1:1 weight ratio) was prepared by dissolving in DCB (Sigma-Aldrich) and stirring for 24 h at 40° C. The resulting mixture was then cooled slowly to ambient temperature.

### Example 3

### Preparation of Solar Cells

In a third example, BHJ solar cells having the structure ITO/PEDOT/P3HT:PCBM/BCP/Al were fabricated by spin-coating the blends of P3HT:PCBM solutions prepared in Examples 1 and 2. Before the fabrication of the devices, the ITO-coated glass substrates were cleaned by scrubbing with detergent and then subjected to ultrasonic treatment sequentially in deionized water, acetone and isopropyl alcohol. The cleaned substrates were then UV-ozone treated for 40 min to remove residual organic contaminants. The cleaned ITO-coated glass substrates were modified by spin-coating a thin layer (˜40 nm) of PEDOT:PSS (Baytron P, Bayer) and cured at 200° C. for 30 min. The active layers were spin-coated in a nitrogen-filled glove box. The spin-coating conditions were optimized for each solution by adjusting the spin-coating speed and time in order to obtain the similar film thickness and drying time for the as-cast films. The as-cast films were dried overnight. After drying, the samples were thermally annealed at 140° C. for 30 min. Finally, the BCP (˜14 nm) and Al cathode (˜100 nm) layers were deposited on top of the active layer by thermal evaporation. Each device had an active area of 0.04 cm² as defined by the overlap of the cathode and anode.

### Example 4

### Electrochemical Evaluation of P3HT/PCBM Solar Cells

The current density (i₀)-voltage characteristics and power conversion efficiency (PCE) values of each cell were then determined in a nitrogen filled glove box under AM 1.5 (100 mWcm⁻²) irradiation.

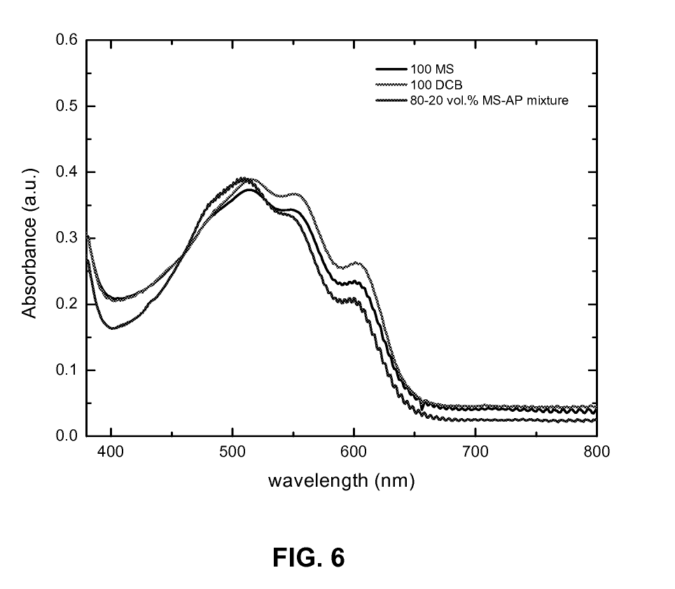

The UV-Vis absorption spectra for the P3HT:PCBM blends cast from DCB, MS, and 80:20 MS:AP, respectively, after thermal annealing at 140° C. for 30 minutes, are illustrated in FIG. 6. The variations in absorption spectra illustrate the differences in films produced from different solvents. For each of the films, an absorption maxima is observed at 510 nm, whereas the shoulder at about 610 nm is indicative of P3HT crystallinity.

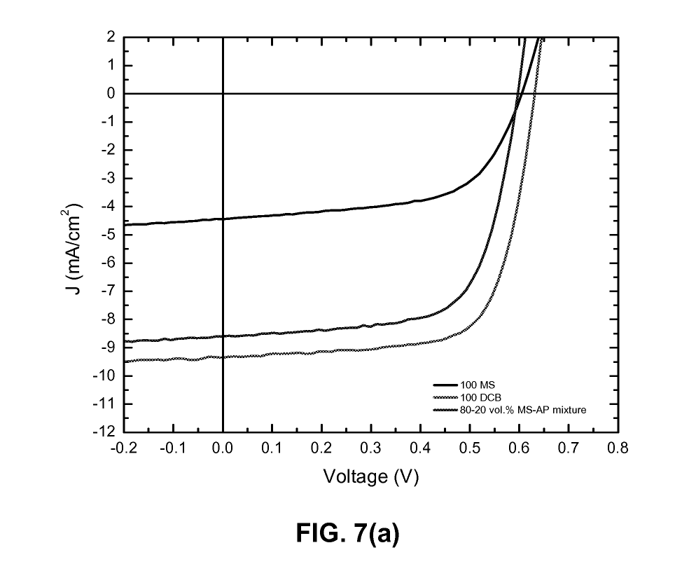

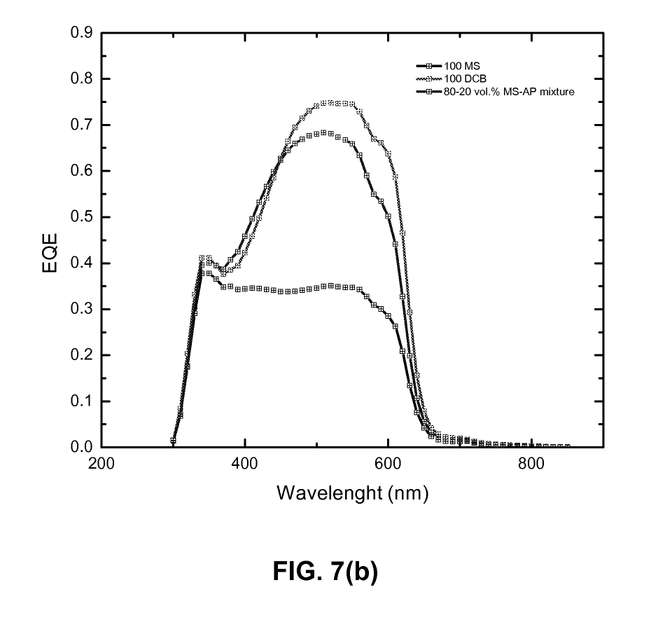

FIG. 7(a) illustrates the J (mA/cm²)-V characteristics of the devices under illumination (100 m@cm−2; AM 1.5 G) and (FIG. 7b) the external quantum efficiency (EQE) for each of the devices. The J-V curve illustrates the significant difference in short circuit current for the device fabricated from MS in comparison to DCB or the 80/20 MS/AP mixture. Upon the addition of 20 vol. % AP to MS, J_{SC} is significantly increased from 4.5 mAcm⁻² to 8.6 mAcm⁻², and R_{SA} decreased from 3.4 Ωcm² for pure MS to 2.8 Ωcm² for the mixture. Moreover, the fill factor is increased from 60% to 67%. These changes in J-V characteristics result in a significant enhancement in power conversion efficiency (PCE) from 1.6% to 3.5% for MS and MS/AP mixture, respectively (over DCB). Additionally, the external quantum efficiency (EQE) data as shown in FIG. 7(b) illustrates a maximum of 35% at 500 nm for the device from MS. In contrast, a device cast from the mixed solvent system resulted in an EQE maximum increased by a factor of two, up to 70% at 500 nm.

As illustrated in FIG. 7(a), the short circuit current and open circuit voltage are both slightly larger for the device prepared from DCB, but the film thickness of the device cast from the mixed solvent system (60 nm) is thinner compared to that of device from DCB (85 nm). Similarly, the ECE for the DCB sample is larger at wavelengths exceeding 500 nm. Table 2, below, summarizes the performance characteristics for each of the three devices.

In one aspect, the performance for the mixed solvent system is reproducible with sample to sample PCE ranging between 3.2% and 3.6%; whereas the performance for the devices prepared from DCB varies between 4% and 4.3%. It is well known that the efficiency for P3HT:PCBM solar cells is thickness sensitive for thicknesses less than approximately 150 nm. Thus, it appears that the performance obtained from the mixed solvent system and DCB are comparable. However, the normal boiling point difference between MS (165° C.) and AP (202° C.) results in significant concentrating of the AP during solvent evaporation in the film formation process. The performance from the 80-20 MS-AP mixture is superior in comparison to 90-10 and 70-30 MS-AP mixtures; thus, the evolution in the solvent quality during film formation can provide improved device performance.

TABLE 2
Summary of device performance for various
BHJ solar cell devices in the work.

| | MS | Mixture | DCB |
|---|---|---|---|
| Thickness | 80 | 60 | 85 |
| (nm) | | | |
| J_{sc}* (mAcm⁻²) | 4.5 | 8.6 | 9.4 |
| V_{oc} (V) | 0.61 | 0.60 | 0.63 |
| R_{SA} (Ωcm²) | 3.4 | 2.8 | 2.6 |
| FF (%) | 60 | 67 | 70 |
| PCE (%) | 1.6 | 3.5 | 4.1 |
| EQE (%) | 35 | 70 | 75 |
| J_{sc}** (mAcm⁻²) | 5.1 | 9.0 | 10.0 |

J_{sc}* current density measured from solar simulator
J_{sc}** current density calculated based on EQE measurement

The improved device performance of the MS/AP mixed solvent system can be attributed to a decrease in the series resistance (see Table 2) due to the improved crystallinity of P3HT upon the addition of AP, and the change in morphology of the active layer caused by the slower evaporation rate of the high boiling point component (AP) upon spin coating and drying process. In one aspect, the changes in device performance can generally be attributed to the processing dependent morphology of the P3HT:PCBM.

### Example 5

### P3HT/PCBM Films Prepared from Mesitylene/Cyclohexanone Solvent System

In another example, solutions of P3HT/PCBM were prepared using mesitylene and a mixture of mesitylene/cyclohexanone (MS/CH). The donor and acceptor materials were combined in the solvent system and heated. The specific concentration and heating temperature of each sample are detailed in Table 3, below. Each solution was then spin coated onto a substrate and annealed.

TABLE 3
Mesitylene/Cyclohexanone

| | Solvent | | Heating | Coating | Annealing |
|---|---|---|---|---|---|
| | (% MS/ | Concentration | Temp | condition | condition |
| Sample | % CH) | (wt. %) | (° C.) | (rpm/sec) | (° C.-min) |
| A | 100/0 | 1.0 | 30 | 650/60 | 140-30 |
| B | 80/20 | 1.0 | 30 | 650/60 | 140-30 |
| C | 100/0 | 1.5 | 50 | 450/35 | 150-30 |
| D | 90/10 | 1.5 | 50 | 450/35 | 150-30 |
| E | 80/20 | 1.5 | 50 | 450/35 | 150-30 |
| F | 70/30 | 1.5 | 50 | 450/35 | 150-30 |

Each of the resulting films was then subjected to electrochemical analysis to determine the current density, open circuit voltage, and conversion efficiency, as detailed in Table 4, below.

TABLE 4
Electrochemical Analysis of MS/CH Samples

| | J_{SC} | | | |
|---|---|---|---|---|
| Sample | (mA/cm²) | V_{OC}(V) | FF | PCE (%) |
| A | 2.58 | 0.43 | 0.46 | 0.6 |
| B | 3.18 | 0.57 | 0.53 | 0.9 |
| C | 5.63 | 0.50 | 0.58 | 1.6 |
| D | 5.00 | 0.50 | 0.57 | 1.4 |
| E | 2.30 | 0.54 | 0.45 | 0.6 |
| F | 3.59 | 0.46 | 0.52 | 0.9 |

### Example 6

### P3HT/PCBM Films Prepared from Mesitylene/Acetophenone Solvent System

In another example, solutions of P3HT/PCBM were prepared using mesitylene and a mixture of mesitylene/acetophenone (MS/AP). The donor and acceptor materials were combined in the solvent system and heated. The specific concentration and heating temperature of each sample are detailed in Table 5, below. Each solution was then spin coated onto a substrate and annealed.

TABLE 5
Mesitylene/Acetophenone

| | Solvent | Concen- | Heating | Coating | Film | Annealing |
|---|---|---|---|---|---|---|
| | (% MS/ | tration | Temp. | condition | Thickness | condition |
| Sample | % AP) | (wt. %) | (° C.) | (rpm/sec) | (nm) | (° C.-min) |
| G | 100/0 | 1.0 | 75 | 650/50 | 55 | 140-30 |
| H | 90/10 | 1.0 | 75 | 700/50 | 65 | 140-30 |
| I | 80/20 | 1.0 | 75 | 750/55 | 60 | 140-30 |
| J | 70/30 | 1.0 | 75 | 750/60 | Unk. | 140-30 |

Each of the resulting films was then subjected to electrochemical analysis to determine the current density, open circuit voltage, and conversion efficiency, as detailed in Table 6, below.

TABLE 6
Electrochemical Analysis of MS/AP Samples

| | J_{SC}* | | | | | J_{SC}** |
|---|---|---|---|---|---|---|
| Sample | (mA/cm²) | V_{OC}(V) | FF | PCE (%) | EQE (%) | (mA/cm²) |
| G | 2.49 | 0.42 | 0.56 | 0.56 | 22 | 2.55 |
| H | 1.22 | 0.53 | 0.43 | 0.24 | 12 | 1.73 |
| I | 8.65 | 0.59 | 0.66 | 3.23 | 72 | 9.25 |
| J | 5.21 | 0.57 | 0.53 | 1.50 | 40 | 4.96 |

J_{sc}* current density based on solar simulator
J_{sc}** current density based on IPCE measurement

### Example 8

### Evaluation of Drying Time

In another example, the effect of drying time of a 1.0 wt %, 80/20 (Mesitylene/Acetophenone) solution (1:1 ratio) on electrochemical performance was analyzed. Samples were prepared by heating to 75° C., and then coated onto a substrate at 700 rpm for 55 sec, to provide a 60 nm film. A first film was dried over a 15 minute period, whereas a second film was dried over a 90 minute period. After drying, each film was annealed at 140° C. for 30 minutes.

The conversion efficiency (PCE %) of the film dried over 15 minutes was 2.98, as compared to 3.46 for the film dried over a 90 minute period.

### Example 8

### Morphological Analysis of P3HT/PCBM Solar Cells

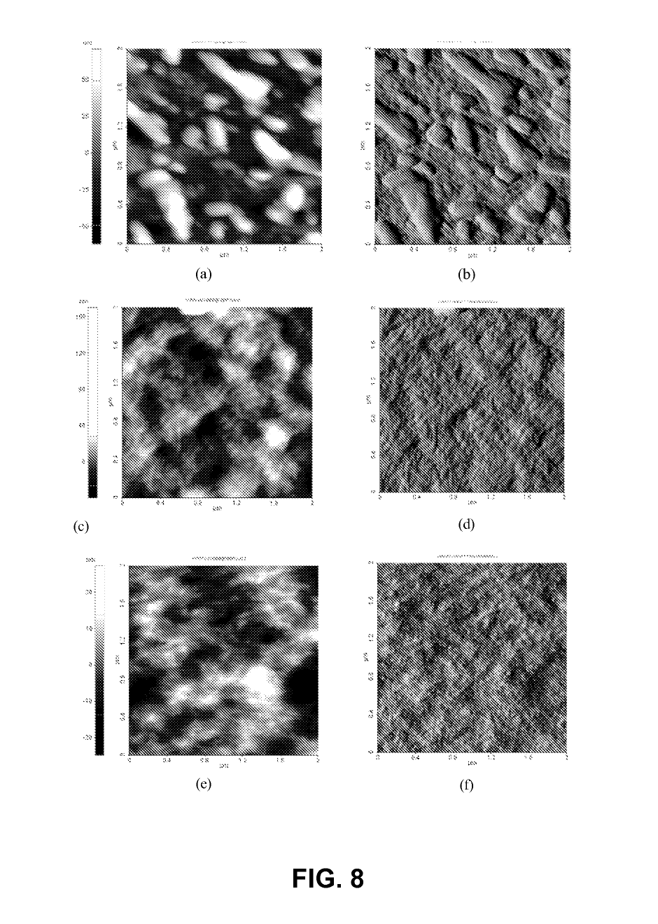

The surface of a BHJ blend, after annealing, can be examined via atomic force microscopy (AFM). FIG. 8 illustrates AFM topography and phase images of P3HT/PCBM blend films cast from (a, b) MS, (c,d) 80 vol. % MS-20 vol. % AP mixture, and (e, f) DCB.

For the film cast from MS, the surface is very rough with large domains. Conversely, no large domains were observed for the film formed from the inventive solvent mixture. While not wishing to be bound by theory, the improved solubility of P3HT/PCBM blend in the mixed solvent system and the slower drying rate of the mixed solvent system (i.e., due to the lower vapor pressure of the AP) result in the improved surface morphology of the film formed from the inventive solvent mixture. The film cast from DCB also exhibited small domain sizes and low surface roughness, with a surface morphology similar to that for the inventive solvent mixture. The morphological analysis supports the data obtained from the electrochemical analysis described above.

What is claimed is:

1. A method for preparing a bulk heterojunction material, the method comprising contacting a donor material and an acceptor material with a solvent system comprising at least two individual solvents, wherein the at least two individual solvents have different boiling points.

2. The method of claim 1, wherein the solvent system does not comprise a halogenated compound.

3. The method of claim 1, wherein the solvent system does not comprise dichlorobenzene.

4. The method of claim 1, wherein the solvent system dissolves at least a portion of the donor material and at least a portion of the acceptor material.

5. The method of claim 1, wherein the solvent system dissolves all or substantially all of both the donor material and the acceptor material.

6. The method of claim 1, wherein at least one of the individual solvents comprises mesitylene, toluene, xylene, or a combination thereof.

7. The method of claim 1, wherein at least one of the individual solvents comprises acetophenone, cyclohexanone, or a combination thereof.

8. The method of claim 1, wherein a concentration of each of the individual solvents varies over time if allowed to evaporate.

9. The method of claim 1, wherein at least one Hansen solubility parameter of the solvent system is substantially similar to that of dichlorobenzene during drying.

10. The method of claim 1, wherein Hansen solubility parameters of the solvent system are substantially similar to those of dichlorobenzene during drying.

11. The method of claim 9, wherein Hansen solubility parameters of the solvent system are substantially similar to those of dichlorobenzene at the point in time when a deposited donor and acceptor material vitrifies or begins to vitrify.
